(19) United States
(12) Patent Application Publication
(10) Pub. No.: US 2026/0153535 A1
(43) Pub. Date: Jun. 4, 2026

(54) TEST DEVICE AND MANUFACTURING METHOD THEREOF

(71) Applicant: InnoLux Corporation, Miao-Li County (TW)

(72) Inventors: Chin-Lung TING, Miao-Li County (TW); Kuang-Ming FAN, Miao-Li County (TW); Lung-Shu HUANG, Miao-Li County (TW)

(73) Assignee: InnoLux Corporation, Miao-Li County (TW)

(21) Appl. No.: 19/380,910

(22) Filed: Nov. 5, 2025

Related U.S. Application Data
(60) Provisional application No. 63/727,201, filed on Dec. 3, 2024.

(30) Foreign Application Priority Data
Jun. 23, 2025 (CN) 202510837710.8

(51) Int. Cl. G01R 1/067; G01R 3/00

(52) U.S. Cl. CPC G01R 1/06716; G01R 3/00

(57) ABSTRACT

A test device includes a flexible detecting film and a supporting layer. The supporting layer supports the flexible detecting film. The flexible detecting film includes at least one probe and at least one first component, the first component overlaps the probe, the first component is disposed between the probe and the supporting layer, the flexible detecting film includes an organic material, and an elongation ratio of the organic material is greater than an elongation ratio of the supporting layer.

### CROSS REFERENCE TO RELATED APPLICATION

This application claims the benefit of U.S. Provisional Application No. 63/727,201, filed on Dec. 3, 2024. The content of the application is incorporated herein by reference.

### BACKGROUND OF THE DISCLOSURE

### 1. Field of the Disclosure

The present disclosure relates to a test device and a manufacturing method thereof, and more particularly to a test device with good test stability, and to a manufacturing method of this test device.

### 2. Description of the Prior Art

As the evolution and development of electronic devices, the electronic devices have become indispensable items. The electronic device includes a variety of required electronic components, so as to enable the electronic device to have required functions.

Normally, the electronic component needs to be tested appropriately and precisely before it is used in the electronic device. In the test of the electronic component, the test result may be affected by the test device (e.g., the electrical effect(s) of the test device, the circuit design of the test equipment, etc.). Namely, the design of the test device affects the accuracy and stability of the test result of the electronic component. For example, the test device may have the low parasitic effect. Therefore, an appropriate design of the test device is required to enhance the test accuracy and the test stability, and to reduce the test error.

### SUMMARY OF THE DISCLOSURE

According to an embodiment, the present disclosure provides a test device including a flexible detecting film and a supporting layer supporting the flexible detecting film. The flexible detecting film includes at least one probe and at least one first component, the first component overlaps the probe, the first component is disposed between the probe and the supporting layer, the flexible detecting film includes an organic material, and an elongation ratio of the organic material is greater than an elongation ratio of the supporting layer.

According to an embodiment, the present disclosure provides a manufacturing method of a test device. The manufacturing method includes: providing a first carrier board; forming at least one insulating layer and at least one conductive layer on the first carrier board to form a film structure, wherein the first carrier board is on a first side of the film structure, the film structure includes at least one first component, and one of the at least one insulating layer includes an organic material; transferring the film structure from the first carrier board to a second carrier board, wherein the second carrier board is on a second side of the film structure, and the second side and the first side are two opposite sides of the film structure; forming at least one probe on the first side of the film structure to form a flexible detecting film including the film structure and the probe, wherein the probe overlaps at least a portion of the first component; and disposing the flexible detecting film on a supporting layer, wherein the first component is disposed between the probe and the supporting layer.

### BRIEF DESCRIPTION OF THE DRAWINGS

FIG. 1 is a schematic diagram showing a cross-sectional view of a test device according to an embodiment of the present disclosure.

FIG. 2 is a schematic diagram showing a cross-sectional view of a flexible detecting film in a first region according to an embodiment of the present disclosure.

FIG. 3 is a schematic diagram showing a top view of a flexible detecting film in a first region according to an embodiment of the present disclosure.

FIG. 4 is a schematic diagram showing structures of components in a flexible detecting film according to an embodiment of the present disclosure.

FIG. 5 is a schematic diagram showing structures of components in a flexible detecting film according to an embodiment of the present disclosure.

FIG. 6 is a schematic diagram showing structures of components in a flexible detecting film according to an embodiment of the present disclosure.

FIG. 7 is a schematic diagram showing structures of components in a flexible detecting film according to an embodiment of the present disclosure.

FIG. 8 is a schematic diagram showing structures of components in a flexible detecting film according to an embodiment of the present disclosure.

FIG. 9 is a schematic diagram showing a cross-sectional view of a flexible detecting film in a first region according to another embodiment of the present disclosure.

FIG. 10 is a schematic diagram showing a test circuit and a unit under test according to an embodiment of the present disclosure.

FIG. 11 is a schematic diagram showing a test circuit and a unit under test according to an embodiment of the present disclosure.

FIG. 12 to FIG. 14 are schematic diagrams showing cross-sectional views of structures at some steps of a manufacturing method of a test device according to an embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of an electronic device in this disclosure, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components with the same function but different names.

In the following description and in the claims, the terms “include”, “comprise” and “have” are used in an open-ended fashion, and thus should be interpreted to mean “include, but not limited to . . . ”. Thus, when the terms “include”, “comprise” and/or “have” are used in the description of the present disclosure, they specify the existence of the corresponding features, regions, steps, operations and/or components, but do not exclude the existence of one or a plurality of the corresponding features, regions, steps, operations and/or components.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, the relative size, thickness, and position of each layer, each region, and/or each structure may be reduced or enlarged for clarity.

When the corresponding component such as layer or region is referred to “on another component”, it may be directly on this another component, or other component(s) may exist between them. On the other hand, when the component is referred to “directly on another component (or the variant thereof)”, any component does not exist between them. Furthermore, when the corresponding component is referred to “on another component”, the two components have a disposition relationship along a top-view/vertical direction, the corresponding component may be below or above the another component, and the disposition relationship along the top-view/vertical direction are determined by an orientation of the device.

It will be understood that when a component or layer is referred to as being “connected to” another component or layer, it can be directly connected to this another component or layer, or intervening components or layers may be presented. In contrast, when a component is referred to as being “directly connected to” another component or layer, there are no intervening components or layers presented. In addition, when the component is referred to “be coupled to/with another component (or the variant thereof)”, it may be directly connected to this another component, or may be indirectly connected (such as electrically connected) to this another component through other component(s).

In the description and following claims, the term “horizontal direction” generally means a direction parallel to a horizontal plane, the term “horizontal plane” generally means a surface parallel to a direction X and direction Y in the drawings, the term “vertical direction” and the term “top-view direction” generally means a direction parallel to a direction Z and perpendicular to the horizontal direction in the drawings, and the direction X, the direction Y and the direction Z are perpendicular to each other. In the description and following claims, the term “top view” generally means a viewing result of viewing along the vertical direction. In the description and following claims, the term “cross-sectional view” generally means a viewing result of cutting a structure along the vertical direction and viewing it along the horizontal direction.

In the description and following claims, it should be noted that the term “overlap” means that two elements overlap along the direction Z, and the term “overlap” can be “partially overlap” or “completely overlap” in unspecified circumstances.

In the description and following claims, the term “width” means that a greatest dimension of a component along a horizontal direction in a cross-sectional view, and the term “thickness” means that a greatest dimension of a component along a vertical direction in a cross-sectional view (e.g., a greatest distance between an lower edge and an upper edge of this component).

The terms “about”, “approximately”, “substantially”, “equal”, or “same” generally mean within ±20% of a given value or range, or mean within ±10%, ±5%, or ±0.5% of a given value or range.

In the description and following claims, an elongation ratio of an object may be measured by any suitable method and/or any suitable equipment. For instance, in a measuring method of the elongation ratio of the object, two points of the object are marked in advance, and a distance between these two points is referred as a gage length; then, the object is stretched by a stretching machine (e.g., universal testing machine (UTM)), such that the gage length is gradually extended during a measuring process, and the elongation ratio of the object is defined as a ratio of a difference between a gage length L′ after the object is broken and the original gage length L before the object is broken to the original gage length L before the object is broken (i.e., the elongation ratio of the object=[(L′−L)/L]×100%). Or, the elongation ratio of the object is defined as an elongation at yield calculated based on an elongation ratio of the object at a yield point (i.e., the longest elongation ratio of the object before the object is permanently deformed). For instance, the elongation ratio of the object may be measured by a standard test method for tensile properties of plastics (e.g., ASTM D638).

Although terms such as first, second, third, etc., may be used to describe diverse constituent elements, such constituent elements are not limited by the terms. These terms are used only to discriminate a constituent element from other constituent elements in the specification, and these terms have no relation to the manufacturing order of these constituent components. The claims may not use the same terms, but instead may use the terms first, second, third, etc. with respect to the order in which an element is claimed. Accordingly, a first constituent element in the description may be a second constituent element in the claims.

In the present disclosure, the electronic device may include a display device, a lighting device, an antenna device, a sensing device, a tiled device, a power module or a combination thereof. Electronic components in the electronic device may include passive component(s) and active component(s), such as capacitor(s), resistor(s), inductor(s), diode(s), switching component(s) (e.g., transistor(s)) and/or integrated circuit(s). The transistor may include a semiconductor structure, a top gate thin film transistor, a bottom gate thin film transistor or a dual gate thin film transistor. The electronic device may have a peripheral system (such as a driving system, a control system, a light system, etc.) for supporting the device(s) and the component(s) in the electronic device.

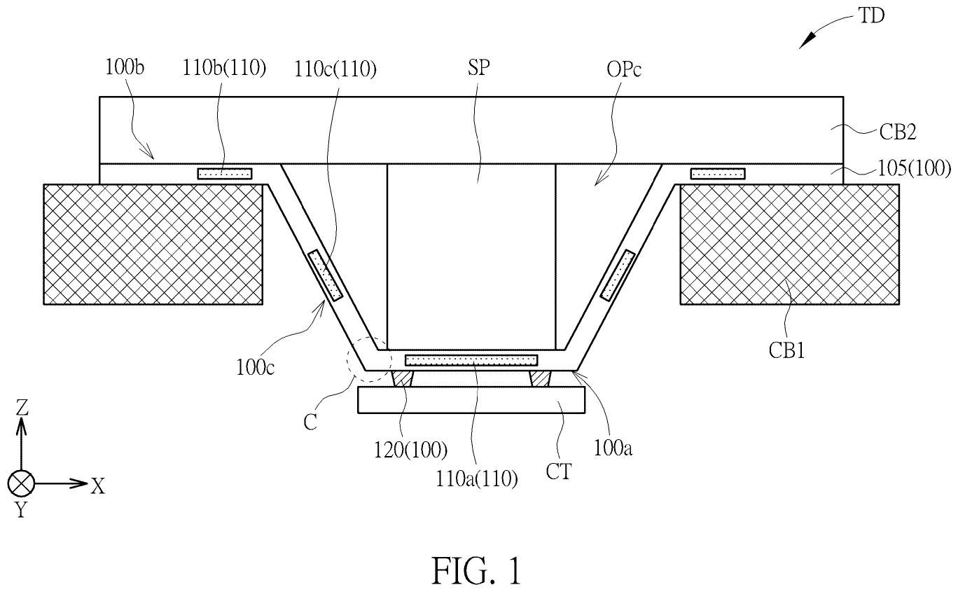

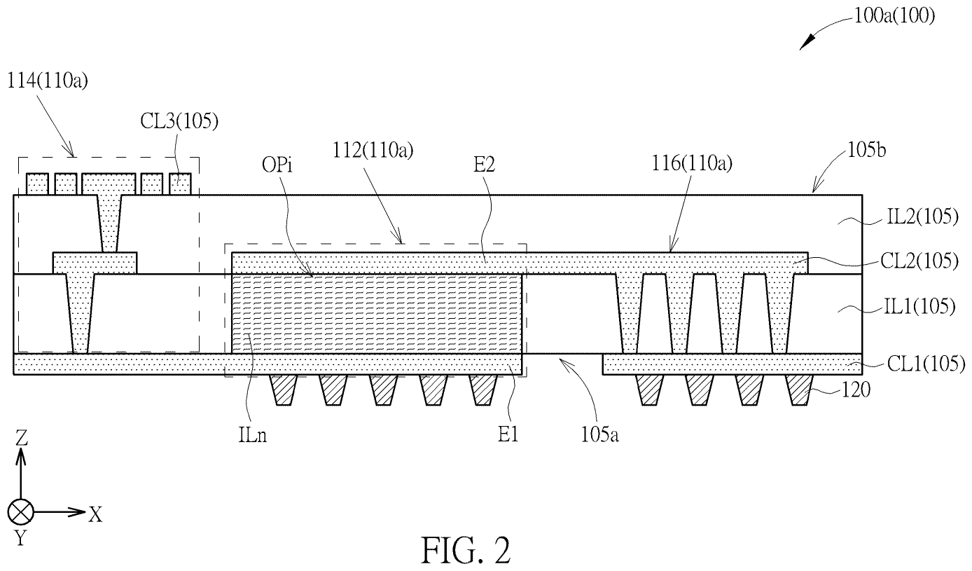

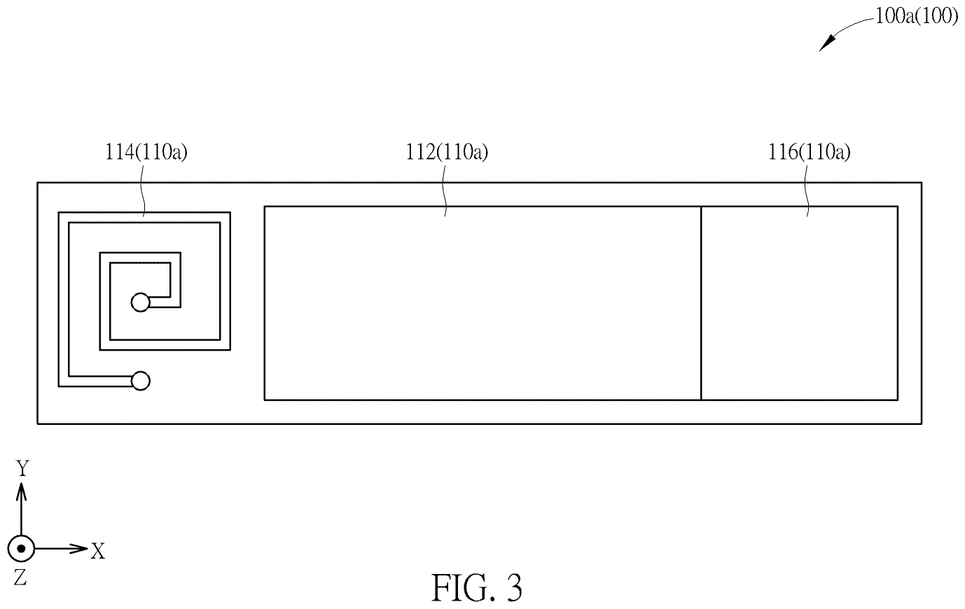

Referring to FIG. 1 to FIG. 3, FIG. 1 is a schematic diagram showing a cross-sectional view of a test device according to an embodiment of the present disclosure, FIG. 2 is a schematic diagram showing a cross-sectional view of a flexible detecting film in a first region according to an embodiment of the present disclosure, and FIG. 3 is a schematic diagram showing a top view of a flexible detecting film in a first region according to an embodiment of the present disclosure. As shown in FIG. 1, the test device TD of the present disclosure is configured to test an electronic component being used in the electronic device, such that the tested electronic component serves as a unit under test CT, wherein there is no restriction on the type of the unit under test CT (e.g., the unit under test CT may be a passive component, an active component or other suitable component), the structure and the test circuit of the test device TD may be correspondingly designed based on the unit under test CT. For instance, the unit under test CT may be an integrated circuit (e.g., power management integrated circuit (PMIC), radio frequency integrated circuit (RFIC) or other suitable integrated circuit), an electronic component needing to be tested or an intermediate product of this electronic component, wherein the intermediate product may include an array substrate, a thin-film transistor (TFT) substrate or other intermediate product needing to be tested.

As shown in FIG. 1, the test device TD includes a supporting layer SP, a flexible detecting film 100 and a first circuit board CB1, wherein the flexible detecting film 100 may be flexible and include at least one conductive structure(s) electrically connected to the unit under test CT, the first circuit board CB1 is electrically connected to the conductive structure of the flexible detecting film 100, the supporting layer SP is configured to support the flexible detecting film 100, and the supporting layer SP makes the flexible detecting film 100 have an appropriate cross-sectional shape to facilitate the conductive structure of the flexible detecting film 100 be electrically connected to the unit under test CT. For instance, in FIG. 1, the flexible detecting film 100 may be disposed between the first circuit board CB1 and the supporting layer SP in the direction Z, such that the flexible detecting film 100 may overlap the supporting layer SP in the direction Z, and the flexible detecting film 100 may overlap the first circuit board CB1 in the direction Z. For instance, the supporting layer SP and the flexible detecting film 100 may be in direct contact with each other.

In the present disclosure, the supporting layer SP may be designed based on requirement(s). For instance, in FIG. 1, a surface of the supporting layer SP adjacent to or in contact with the flexible detecting film 100 may be a flat horizontal plane. For instance, in FIG. 1, a rigidity of the supporting layer SP may be greater than a rigidity of the flexible detecting film 100, and a thickness of the supporting layer SP may be greater than a thickness of the flexible detecting film 100. For instance, an elongation ratio of the supporting layer SP may be less than 50% or lower than an elongation ratio of the flexible detecting film 100. Note that a normal direction of the supporting layer SP may be parallel to the direction z.

The first circuit board CB1 may include any suitable electronic component and any suitable circuit, so as to be electrically connected to the conductive structure of the flexible detecting film 100. Optionally, the first circuit board CB1 may be electrically connected to the unit under test CT through the conductive structure of the flexible detecting film 100. Optionally, an outer device may be electrically connected to the conductive structure of the flexible detecting film 100 and the unit under test CT through the first circuit board CB1. In addition, the first circuit board CB1 may include a first substrate, wherein the electronic component and the circuit of the first circuit board CB1 may be disposed on the first substrate. For instance, the first substrate may include resin, a glass fiber substrate, glass, quartz, ceramic, sapphire, polymer, a substrate with through hole(s), any other suitable material or a combination thereof. Then, build-up layers may be respectively formed on two opposite sides of the first substrate. The build-up layer may include at least one insulating material and at least one conductive material alternately stacked along the direction Z, wherein the insulating material may include Ajinomoto build-up film (ABF), photosensitive polyimide (PSPI), inorganic compound or a combination thereof, and the conductive material may include copper, copper foil or other film with conductive material. Note that a normal direction of the first circuit board CB1 may be parallel to the direction Z.

In FIG. 1, the first circuit board CB1 has a circuit board opening OPc, and the supporting layer SP passes through the circuit board opening OPc and protrudes from the first circuit board CB1. Namely, the circuit board opening OPc may make the first circuit board CB1 have a plurality sub-parts separated from each other. For example, in FIG. 1, at least two sub-parts of the first circuit board CB1 are separated from each other along the direction X, wherein the direction X is perpendicular to the direction Z. For instance, in FIG. 1, in the direction Z, the thickness of the supporting layer SP may greater than a thickness of the first circuit board CB1, such that the supporting layer SP may protrude from the first circuit board CB1 in the condition that the supporting layer SP passes through the circuit board opening OPc. For instance, the circuit board opening OPc may be a through hole or a trough opening.

As shown in FIG. 1, since the flexible detecting film 100 is flexible, the flexible detecting film 100 may have a suitable cross-sectional shape based on the design of the supporting layer SP. For instance, in FIG. 1, the cross-sectional shape of the flexible detecting film 100 may be a trapezoidal shape, a U-shaped shape or other suitable shape after assembling. For instance, when the cross-sectional shape of the flexible detecting film 100 is a U-shaped shape after assembling, a turning point C of the flexible detecting film 100 may be arc-shaped. According to some embodiments, when the cross-sectional shape of the flexible detecting film 100 is a U-shaped shape, the cracking risk at the turning point C may be reduced. According to some embodiments, in the flexible detecting film 100, a part of the insulating layer corresponding to the turning point C may have an opening design or a mesh design, so as to enhance the flexibility of the turning point C. Moreover, the flexible detecting film 100 may be divided into different regions according to the position of the supporting layer SP and the position of the first circuit board CB1. For instance, in FIG. 1, the flexible detecting film 100 may include a first region 100a, a second region 100b and a third region 100c, the supporting layer SP may overlap the first region 100a and not overlap the second region 100b and the third region 100c in the direction Z, the first circuit board CB1 may overlap the second region 100b and not overlap the first region 100a and the third region 100c in the direction Z, the third region 100c may be between the first region 100a and the second region 100b, the first region 100a and the third region 100c may be disposed in the circuit board opening OPc, and the third region 100c may be disposed between the first circuit board CB1 and the supporting layer SP in the horizontal direction. For instance, the first region 100a and the second region 100b of the flexible detecting film 100 may be substantially parallel to the direction X and the direction Y (i.e., the first region 100a and the second region 100b of the flexible detecting film 100 may be horizontal planes substantially), and the third region 100c of the flexible detecting film 100 may be a inclined plane connected between the first region 100a and the second region 100b.

In the present disclosure, as shown in FIG. 1 and FIG. 2, the flexible detecting film 100 may include a film structure 105 including an organic material, such that the flexible detecting film 100 may be flexible. For instance, the organic material may include PI, PSPI, silane coupling material, photosensitive material, other suitable organic material or a combination thereof. For instance, an elongation ratio of the organic material may be greater than 50% or greater than the elongation ratio of the supporting layer SP.

In the present disclosure, the film structure 105 may include a plurality of layers stacked along the direction Z. In some embodiments, the film structure 105 of the flexible detecting film 100 may include at least one insulating layer, at least one conductive layer, any other suitable layer or a combination thereof. For instance, the conductive layer may include metal, transparent conductive material, any other suitable conductive material or a combination thereof, and the insulating layer may include silicon oxide (SiOₓ), silicon nitride (SiN_{y}), silicon oxynitride (SiOₓN_{y}), oxide, organic material, any other suitable insulating material or a combination thereof. Thus, at least one insulating layer in the film structure 105 of the flexible detecting film 100 may include aforementioned organic material, so as to make the flexible detecting film 100 flexible. For instance, in FIG. 2, the film structure 105 of the flexible detecting film 100 may include a conductive layer CL1, an insulating layer IL1, a conductive layer CL2, an insulating layer IL2 and a conductive layer CL3, wherein the insulating layer IL1 may be configured to separate a portion of the conductive layer CL1 from a portion of the conductive layer CL2, and the insulating layer IL2 may be configured to separate a portion of the conductive layer CL2 from a portion of the conductive layer CL3. For instance, the insulating layers IL1 and IL2 may include the organic material, and the conductive layers CL1, CL2 and CL3 may include metal.

In FIG. 2, the film structure 105 may have a first side 105a and a second side 105b opposite to each other in the direction Z, the first side 105a may be near the conductive layer CL1, and the second side 105b may be near the conductive layer CL3.

The film structure 105 of the flexible detecting film 100 may include at least one component 110, and the component 110 may include the conductive layer(s) of the film structure 105 (e.g., the conductive layer CLy), the insulating layer(s) of the film structure 105 (e.g., the insulating layer(s) ILx), other layer(s) of the film structure 105 or a combination thereof. In the present disclosure, the component 110 of the film structure 105 may be designed according to the unit under test CT to form a suitable circuit, and the first circuit board CB1 may be electrically connected to at least one of the component(s) 110 of the film structure 105. For instance, the component 110 may include a capacitor 112, an inductor 114, a grounding structure 116, any other suitable component or a combination thereof, and a number of the component(s) 110 in the film structure 105 may be designed based on requirement(s). For instance, the capacitor 112 may be a parallel-plate capacitor, a comb type capacitor or any other suitable capacitor, the inductor 114 may be a two dimensions (2D) spiral inductor, a three dimensions (3D) spiral inductor, any other suitable inductor.

In some embodiments (as shown in FIG. 2 and FIG. 3), when the capacitor 112 of the film structure 105 is a parallel-plate capacitor, two electrodes E1 and E2 of the capacitor 112 may respectively belong to different conductive layers in the film structure 105, and a dielectric layer may belong to one insulating layer in the film structure 105 and be between two electrodes E1 and E2. For instance, in FIG. 2, two electrodes E1 and E2 of the capacitor 112 may respectively belong to the conductive layer CL1 and the conductive layer CL2, and the dielectric layer of the capacitor 112 may be included in an insulating layer between two electrodes E1 and E2. In some embodiments, an insulating layer with a higher dielectric constant may be disposed between two electrodes E1 and E2, so as to enhance a capacitance of the capacitor 112. For instance, at 10 GHZ, the dielectric constant of this insulating layer may be greater than or equal to 3 F/m. For instance, in FIG. 2, the film structure 105 may further include an inorganic material dielectric layer ILn (insulating layer) disposed between the conductive layer CL1 and the conductive layer CL2, so as to serve as the dielectric layer of the capacitor 112 (i.e., the capacitor 112 may include the electrode E1 of the conductive layer CL1, the electrode E2 of the conductive layer CL2 and the inorganic material dielectric layer ILn), wherein a dielectric constant of the inorganic material dielectric layer ILn may be greater than a dielectric constant of the organic material, a dielectric constant of the insulating layer IL1 and a dielectric constant of the insulating layer IL2. The inorganic material dielectric layer ILn may be designed based on requirement(s) and include any suitable inorganic insulating material, and the capacitance of the capacitor 112 may be adjusted by adjusting the thickness and/or the dielectric constant of the inorganic material dielectric layer ILn. For instance, the inorganic material dielectric layer ILn may include silicon oxide, silicon nitride, silicon oxynitride, any other oxide or a combination thereof. For instance, the inorganic material dielectric layer ILn may be a single-layer structure or a multi-layer structure, and the thickness of the inorganic material dielectric layer ILn may be greater than or equal to 1000 Å and less than or equal to 5000 Å. For instance, in FIG. 2, the insulating layer IL1 has an insulating opening OPi, and the inorganic material dielectric layer ILn is disposed in the insulating opening OPi, so as to make the inorganic material dielectric layer ILn overlap the electrode E1 of the conductive layer CL1 and the electrode E2 of the conductive layer CL2 in the direction Z.

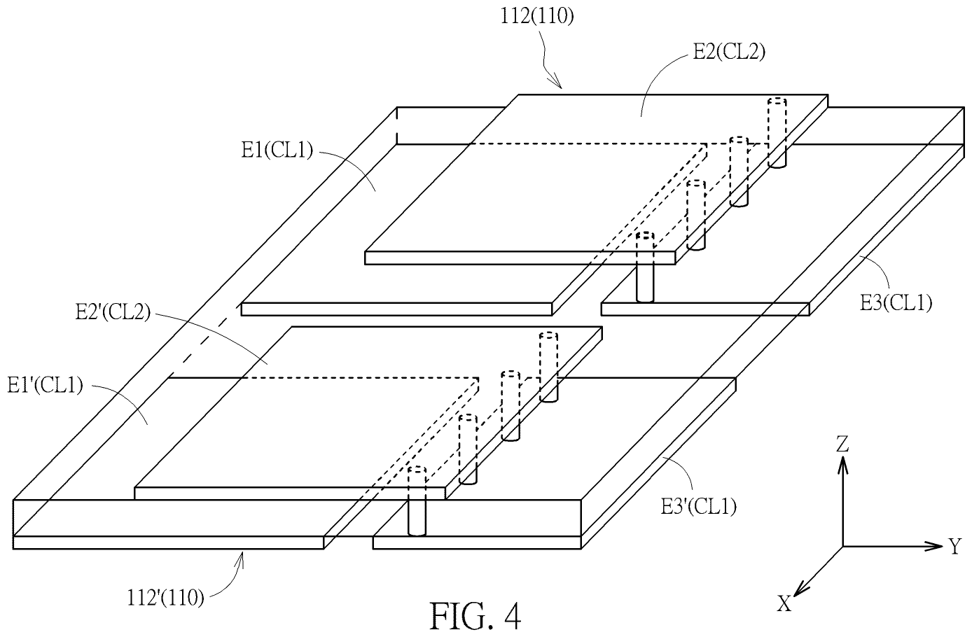

In an embodiment shown in FIG. 4, the film structure 105 includes a capacitor 112 (the capacitor 112 includes electrodes E1 and E2) and a capacitor 112′ (the capacitor 112′ includes electrodes E1′ and E2′) which are separated from each other, wherein the capacitors 112 and 112′ are parallel-plate capacitors. The capacitor 112 includes a portion of the conductive layer CL1, a portion of the conductive layer CL2 and a portion of the dielectric layer disposed between the conductive layer CL1 and the conductive layer CL2, and the capacitor 112′ includes a portion of the conductive layer CL1, a portion of the conductive layer CL2 and a portion of the dielectric layer disposed between the conductive layer CL1 and the conductive layer CL2. In another embodiment, the electrodes E2 and E2′ are grounded by being connected two electrodes E3 and E3′ shown in FIG. 4 to the grounding structure.

For instance, if the capacitor 112 of the film structure 105 is a comb type capacitor (not shown in figures), in the cross-sectional view, two electrodes of the capacitor 112 may belong to the same conductive layer of the film structure 105 or two electrodes of the capacitor 112 may be disposed on the same plane, and two electrodes may be separated by a gap in the horizontal direction and not be connected to each other.

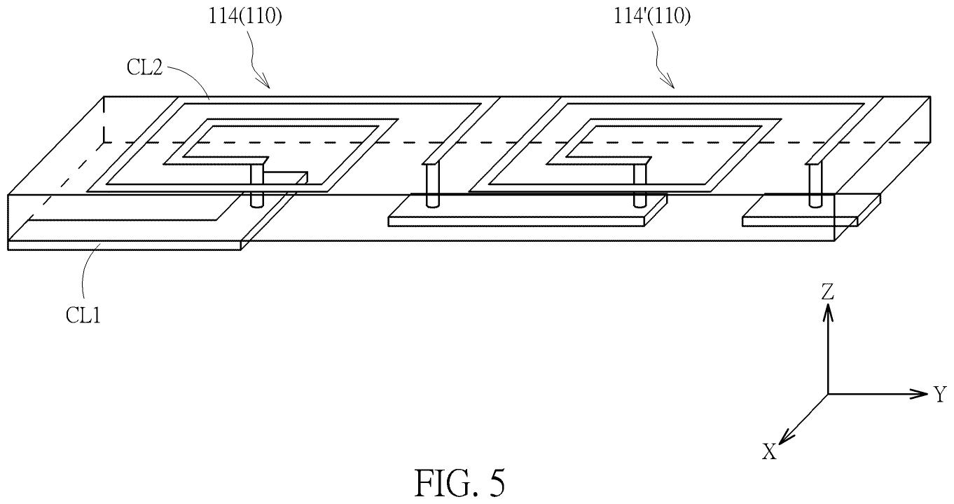

As shown in FIG. 2 and FIG. 3, if the inductor 114 of the film structure 105 is a 2D spiral inductor, a spiral structure of the inductor 114 is included in one conductive layer of the film structure 105. In an embodiment shown in FIG. 5, the film structure 105 may include two inductors 114 and 114′ connected in series, wherein the conductive layer CL2 may include two inductors 114 and 114′, and the conductive layer CL1 may include a trace configured to be connected two inductors 114 and 114′ for making them connected in series.

If the inductor 114 of the film structure 105 is a 3D spiral inductor (not shown in figures), a spiral structure of the inductor 114 may be included in a plurality of conductive layers of the film structure 105.

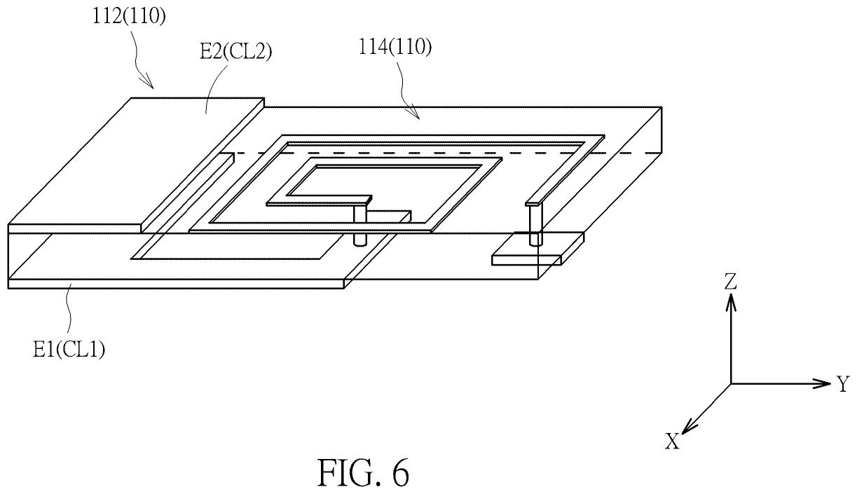

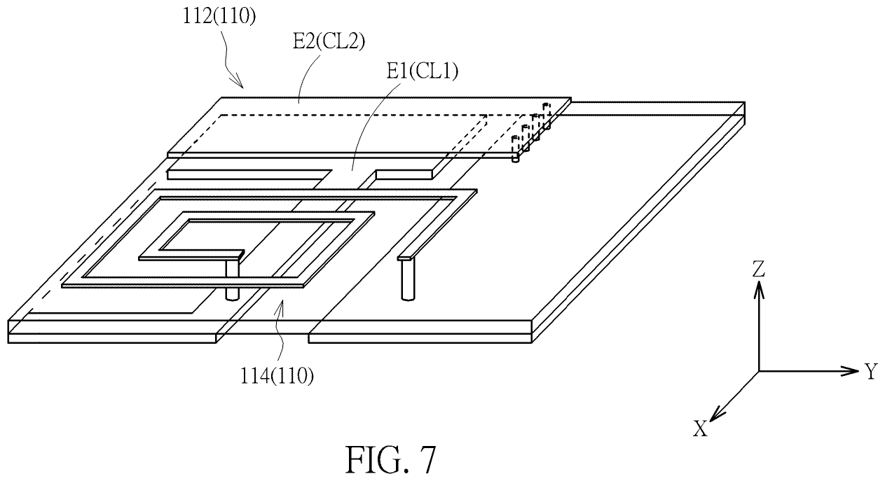

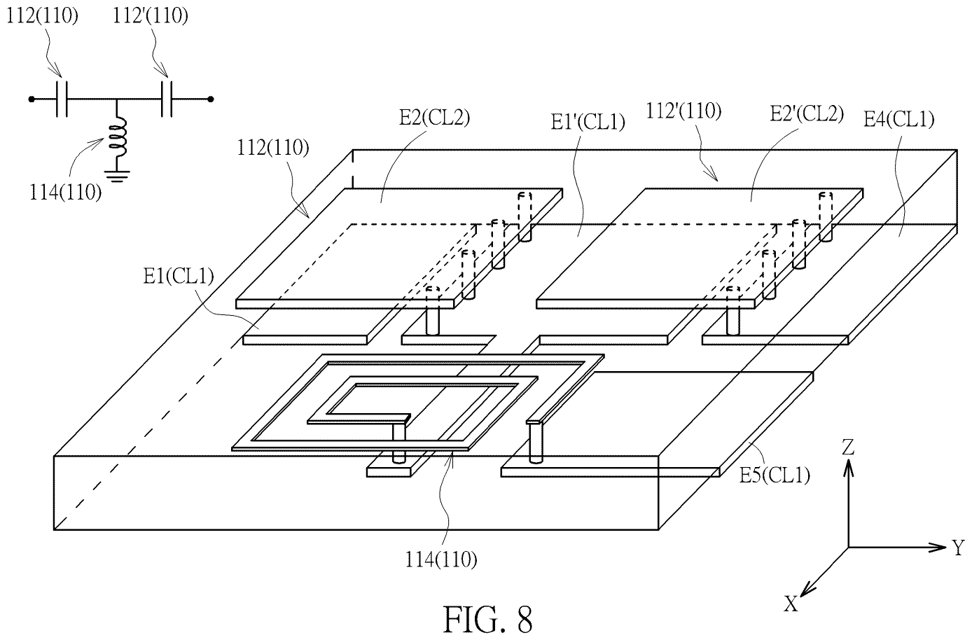

Moreover, in embodiments shown in FIG. 6 to FIG. 8, the film structure 105 includes the capacitor 112 and the inductor 114. As shown in FIG. 6, the capacitor 112 and the inductor 114 of the film structure 105 may be connected in series. As shown in FIG. 7, the capacitor 112 and the inductor 114 of the film structure 105 may be connected in parallel. As shown in FIG. 8, two capacitors 112 and 112′ and the inductor 114 of the film structure 105 may be connected to form a T-type circuit, wherein the electrodes E1 and E4 may serve as two terminals of the T-type circuit, and the electrode E5 may be connected to the grounding structure. In some embodiments (not shown in figures), at least one parallel-plate capacitor and at least one 2D spiral inductor of the film structure 105 may be connected to form a n-type circuit.

The type of the component 110 in the film structure 105 and the design of the circuit in the film structure 105 are not limited to the above, and they could be correspondingly adjusted based on the type of the unit under test CT and/or any other requirement.

As shown in FIG. 1 to FIG. 3, at least one of the component(s) 110 of the film structure 105 of the flexible detecting film 100 may be disposed in the first region 100a of the flexible detecting film 100, so as to overlap the supporting layer SP in the direction Z, wherein the component(s) 110 disposed in the first region 100a of the flexible detecting film 100 may be referred as first component(s) 110a, and at least one of the first component(s) 110a may be electrically connected to the first circuit board CB1. In some embodiments (as shown in FIG. 2 and FIG. 3), the first component(s) 110a may include the capacitor 112, and the first component(s) 110a may optionally include any other suitable component. For instance, in FIG. 2 and FIG. 3, the first components 110a may include the capacitor 112, the inductor 114 and the grounding structure 116, wherein the capacitor 112, the inductor 114 and the grounding structure 116 may be electrically connected to each other. At least a portion of the first component(s) 110a may overlap at least a portion of the supporting layer SP.

Optionally, one or some of the component(s) 110 of the film structure 105 of the flexible detecting film 100 may be disposed in the second region 100b of the flexible detecting film 100, so as to overlap the first circuit board CB1 in the direction Z, wherein the component(s) 110 disposed in the second region 100b of the flexible detecting film 100 may be referred as second component(s) 110b. The second component(s) 110b may include any suitable component based on requirement(s), and one of the second component(s) 110b may be electrically connected to the first circuit board CB1. For instance, the second component(s) 110b may include a connecting pad connected to the first circuit board CB1.

Optionally, one or some of the component(s) 110 of the film structure 105 of the flexible detecting film 100 may be disposed in the third region 100c of the flexible detecting film 100, wherein the component(s) 110 disposed in the third region 100c of the flexible detecting film 100 may be referred as third component(s) 110c. The third component(s) 110c may include any suitable component based on requirement(s). For instance, at least one of the third component(s) 110c may be electrically connected to the first circuit board CB1.

Furthermore, in some embodiments, the film structure 105 of the flexible detecting film 100 may have an effect of a redistribution layer (RDL) through the design of the conductive layer. Namely, through the design of the conductive layer of the film structure 105, the film structure 105 may have an effect of redistributing conductive traces, have an effect of increasing a fan-out area of conductive traces and/or make different electronic components be electrically connected to each other. For instance, in the film structure 105, through the design of the conductive layer, an input-output pin related to the unit under test may be redistributed. For example, if the redistributing structure is used in a package device, the redistributing structure may be a component electrically connected between chips. For example, if the redistributing structure is used in a test device, a bonding effect between the unit under test and the circuit board may be enhanced because of the redistributing structure.

As shown in FIG. 1 and FIG. 2, the flexible detecting film 100 further includes at least one the probe 120 configured to be electrically connected to the unit under test CT, wherein the probe 120 is disposed on a side of the film structure 105 opposite to the supporting layer SP, such that the film structure 105 is disposed between the probe 120 and the supporting layer SP. For instance, the probe 120 may be in direct contact with the unit under test CT to be electrically connected to the unit under test CT. In the present disclosure, the probe 120 may be designed based on requirement(s). For instance, the probe 120 may include an elastic material (e.g. insulating material 122) and a conductive material, wherein the elastic material may be configured to reduce and/or avoid the damage to the unit under test CT caused by being in direct contact with the probe 120 and the unit under test CT, the conductive material may be configured to be electrically connected to the component 110 (e.g., the first component 110a) of the film structure 105 and the unit under test CT. For instance, conductive material may include metal, transparent conductive material, any other suitable conductive material or a combination thereof. For instance, in the probe 120, the conductive material may be disposed on the elastic material. In the present disclosure, the elastic material may be an insulating material with an elongation ratio ranging from 20% to 900%, ranging from 30% to 500%, ranging from 50% to 300% or greater than an elongation ratio of an insulating layer of a circuit structure.

In FIG. 1 and FIG. 2, the probe 120 may be disposed in the first region 100a of the flexible detecting film 100. Therefore, the first component 110a of the film structure 105 may be disposed between the probe 120 and the supporting layer SP, and the probe 120 may overlap the first component 110a and the supporting layer SP in the direction Z. In the present disclosure, the probe 120 may be electrically connected to the component 110 of the film structure 105, such that the component 110 of the film structure 105 may be electrically connected to the unit under test CT through the probe 120. Optionally, the probe 120 may be electrically connected to the first circuit board CB1 through the component 110 of the film structure 105.

In the present disclosure, since the component 110 of the flexible detecting film 100 is integrated in the film structure 105, and the first component 110a and the probe 120 of the flexible detecting film 100 are overlapped with each other in the direction Z, a distance between the first component 110a of the flexible detecting film 100 and the unit under test CT is reduced (e.g., the distance may be less than or equal to 15 mm or less than or equal to 10 mm), such that a length of the signal trace is reduced, so as to reduce the parasitic effect caused by the test device TD, thereby enhancing the test accuracy and the test stability of the test device TD and reducing the test error of the test device TD. In addition, the flexible detecting film 100 of the present disclosure is flexible, the life of the test device TD is increased and/or the cost of the test device TD is decreased.

Moreover, the test device TD may optionally include any other required structure. For instance, as shown in FIG. 1, the test device TD may further include a second circuit board CB2 configured to serve as a base of the supporting layer SP for supporting the supporting layer SP, wherein the supporting layer SP may be disposed between the flexible detecting film 100 and the second circuit board CB2 in the direction Z. In the present disclosure, the supporting layer SP may be disposed on the second circuit board CB2 through any suitable manner. For instance, the supporting layer SP may be connected to the second circuit board CB2 through an adhering structure, a connecting structure (e.g., a fastener) or any other suitable manner, and the supporting layer SP may be optionally electrically connected to a conductive structure of the second circuit board CB2.

Optionally, the second circuit board CB2 may be connected to the first circuit board CB1 through any suitable manner. For instance, the second circuit board CB2 may be connected to the first circuit board CB1 through an adhering structure (e.g., an adhering layer), a connecting structure (e.g., a fastener) or any other suitable manner, and the conductive structure of the second circuit board CB2 may be optionally electrically connected to the conductive structure of the first circuit board CB1. Optionally, the conductive structure of the second circuit board CB2 may be optionally electrically connected to the component 110 of the flexible detecting film 100 and/or the unit under test CT. Optionally, the second circuit board CB2 may be electrically connected to the outer device.

The test circuit of the test device TD may include the circuit in the flexible detecting film 100, and the test circuit may optionally include the circuit in the first circuit board CB1 and/or the circuit in the second circuit board CB2. Furthermore, a signal input terminal of the test circuit of the test device TD may be disposed in the first circuit board CB1 and/or the second circuit board CB2 based on requirement(s), and a signal output terminal of the test circuit of the test device TD may be disposed in the first circuit board CB1 and/or the second circuit board CB2 based on requirement(s).

The second circuit board CB2 may include a second substrate, wherein the circuit and the electronic component of the second circuit board CB2 may be disposed on the second substrate. For instance, the second substrate may include glass, quartz, ceramic, sapphire, polymer, any other suitable material or a combination thereof. For instance, the second substrate may include a laminate or any other board having conductive material(s). Note that a normal direction of the second circuit board CB2 may be parallel to the direction Z.

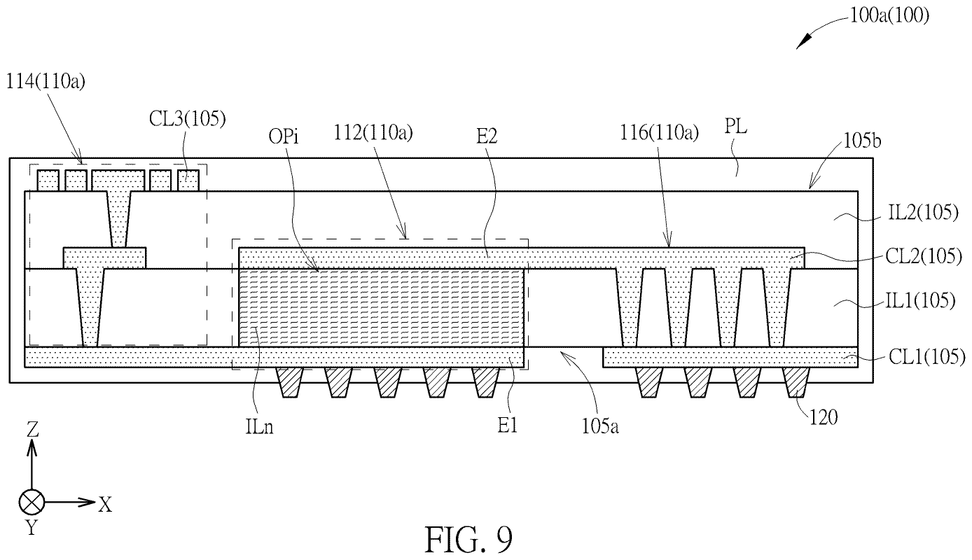

Moreover, in an embodiment shown in FIG. 9, the test device TD may further include a protective layer PL configured to protect the flexible detecting film 100. The protective layer PL may be designed based on requirement(s), and the protective layer PL may include any suitable material. For instance, the material of the protective layer PL may include an organic insulating material or an inorganic insulating material, and the protective layer PL may have a hygroscopic property better than the hygroscopic property of the flexible detecting film 100. For instance, an elongation ratio of the protective layer PL may be less than 50%. For instance, in FIG. 9, the flexible detecting film 100 may be surrounded by or coated with the protective layer PL which may cover the first side 105a, the second side 105b and a sidewall of the film structure 105 of the flexible detecting film 100, such that the flexible detecting film 100 is protected by the protective layer PL. In FIG. 9, the protective layer PL may not cover an end of the probe 120 configured to be in contact with the unit under test CT, so as to avoid affecting the test function of the test device TD.

The test device of the present disclosure is not limited to the above embodiments. A test method of the test device of the present disclosure will be described in the following, but the test method of the present disclosure is not limited to the following embodiment(s).

As shown in FIG. 1, in the test method of the present disclosure, the test device TD is in direct contact with the unit under test CT through the probe 120, so as to test the unit under test CT. In detail, the test device TD is aligned with the unit under test CT, and then, the probe 120 of the flexible detecting film 100 of the test device TD is in direct contact with the unit under test CT. Afterward, a testing signal is provided to the signal input terminal of the test circuit in the test device TD through the outer device, and then, the outer device receives a signal outputted from the signal output terminal of the test circuit in the test device TD, so as to analyze the signal, thereby confirming whether the unit under test CT meets the standard and determining whether the unit under test CT passes the test.

In the present disclosure, the unit under test CT may be an electronic component which has not been disposed in the electronic device, an electronic component which has been disposed in the electronic device, an electronic component before packaged or an electronic component after packaged. For instance, if the unit under test CT is an integrated circuit, the integrated circuit may be tested while it is still in the wafer and not cut, the integrated circuit may be tested after it is packaged, or the integrated circuit may be tested at any other suitable stage.

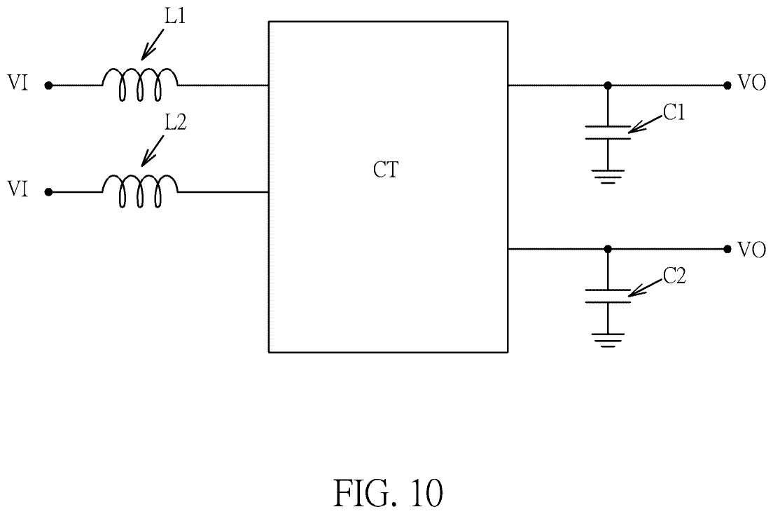

For instance, if the test device TD tests a PMIC (i.e., the unit under test CT is a PMIC), the test circuit shown in FIG. 10 may be provided. For instance, in the test circuit shown in FIG. 10, capacitors C1 and C2 and inductors L1 and L2 may belong to the components 110 of the film structure 105 of the flexible detecting film 100. Therefore, the capacitors C1 and C2 electrically connected to the signal output terminal VO may belong to the first component(s) 110a of the first region 100a, and the inductors L1 and L2 electrically connected to the signal input terminal VI may individually belong to the first component(s) 110a of the first region 100a, the second component(s) 110b of the second region 100b or the third component(s) 110c of the third region 100c.

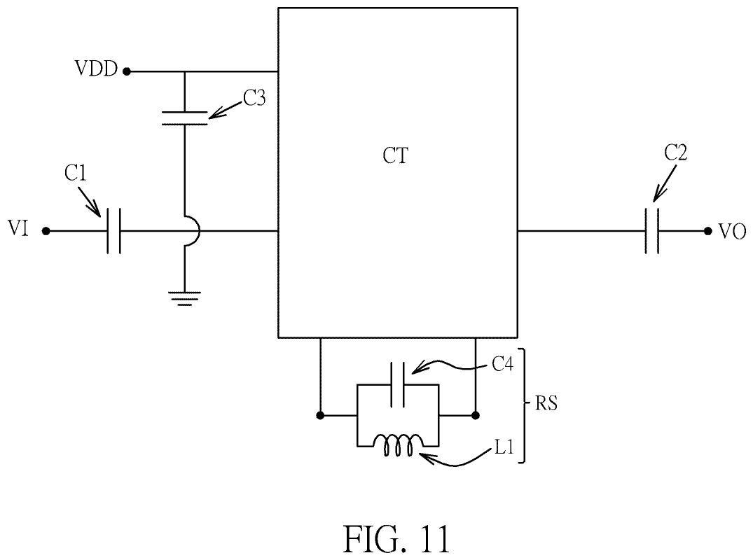

For instance, if the test device TD tests a RFIC (i.e., the unit under test CT is a RFIC), the test circuit shown in FIG. 11 may be provided, wherein a resonator RS may include at least one capacitor C4 and at least one inductor L1. For instance, in the test circuit shown in FIG. 11, capacitors C1, C2, C3 and C4 and an inductor L1 may belong to the components 110 of the film structure 105 of the flexible detecting film 100. Therefore, at least one of the capacitor C1 electrically connected to the signal input terminal VI, the capacitor C2 electrically connected to the signal output terminal VO, the capacitor C3 electrically connected to a signal source VDD and the capacitor C4 of the resonator RS may belong to the first component(s) 110a of the first region 100a, other capacitor(s) may individually belong to the second component(s) 110b of the second region 100b or the third component(s) 110c of the third region 100c, and the inductor L1 of the resonator RS may belong to the first component(s) 110a of the first region 100a, the second component(s) 110b of the second region 100b or the third component(s) 110c of the third region 100c.

A manufacturing method of a test device of the present disclosure will be described in the following, but the manufacturing method of the present disclosure is not limited to the following embodiment(s) and figures.

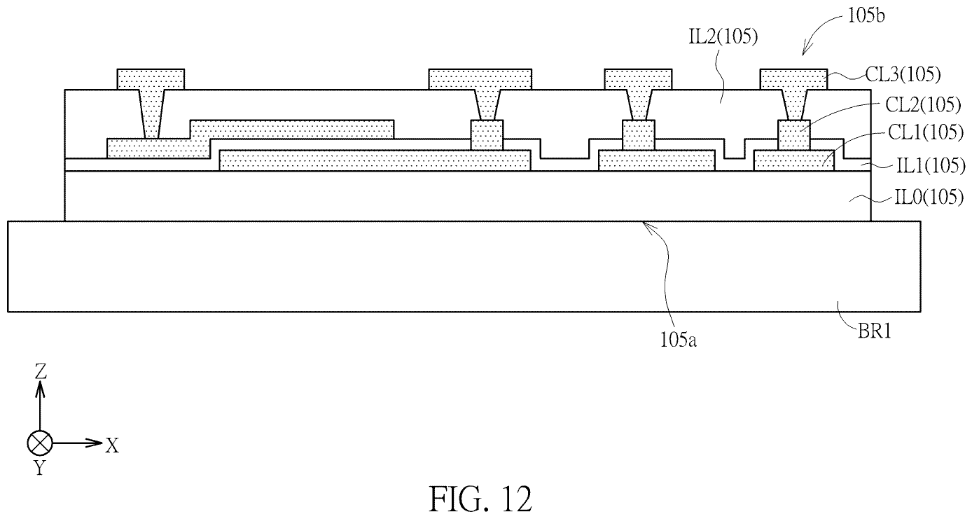

Referring to FIG. 12 to FIG. 14, FIG. 12 to FIG. 14 are schematic diagrams showing cross-sectional views of structures at some steps of a manufacturing method of a test device according to an embodiment of the present disclosure. In some embodiments, any other suitable step may be added before or after one of the existing steps of the manufacturing method, and/or some steps may be performed simultaneously or separately. In some embodiments, the process sequence of the manufacturing method may be adjusted based on requirement(s).

In the following manufacturing method, a forming process of a layer and/or a structure may include an atomic layer deposition (ALD), a chemical vapor deposition (CVD), a physical vapor deposition (PVD), a coating process, an electroplating process, any other suitable process or a combination thereof. In the following manufacturing method, a patterning process may include a photolithography, an etching process, a developing process, any other suitable process or a combination thereof, wherein the etching process may be a wet etching process, a dry etching process, any other suitable etching process or a combination thereof.

As shown in FIG. 12, a first carrier board BR1 is provided. In the present disclosure, the first carrier board BR1 may include any suitable material. For instance, the first carrier board BR1 may include glass, quartz, ceramic, sapphire, silicon, glass fiber, polymer, any other suitable material or a combination thereof.

As shown in FIG. 12, the insulating layer IL0 is formed on the first carrier board BR1, the conductive layer CL1 is formed on the insulating layer IL0, the insulating layer IL1 is formed on the conductive layer CL1, the conductive layer CL2 is formed on the insulating layer IL1, the insulating layer IL2 is formed on the conductive layer CL2, and the conductive layer CL3 is formed on the insulating layer IL2. Moreover, the inorganic material dielectric layer ILn (e.g., FIG. 2) may be formed on the conductive layer CL1. The insulating layer ILx (x=0, 1, 2 . . . ) and the conductive layer CLy (y=0, 1, 2 . . . ) may be a single-layer structure or a multi-layer structure. For instance, the patterning process performed on the insulating layer ILx and the conductive layer CLy may be a photolithography, such that a photoresist layer may be formed on the conductive layer CLy, and the conductive layer CLy may be patterned by an exposure step, a developing step and an etching step.

As shown in FIG. 12, the formed film structure 105 includes the insulating layer IL0, the conductive layer CL1, the insulating layer IL1, the inorganic material dielectric layer ILn (e.g., FIG. 2), the conductive layer CL2, the insulating layer IL2 and the conductive layer CL3 stacked staggered along the direction Z on the first carrier board BR1 which is on the first side 105a of the film structure 105. Namely, at least one insulating layer and at least one conductive layer are formed on the first carrier board BR1 to form the film structure 105, and the first carrier board BR1 is on the first side 105a of the film structure 105. In the film structure 105, at least one of the insulating layer IL0, the insulating layer IL1 and the insulating layer IL2 includes the organic material, and the dielectric constant of the inorganic material dielectric layer ILn may be greater than the dielectric constant of the organic material and the dielectric constants of the insulating layers IL0, IL1 and IL2.

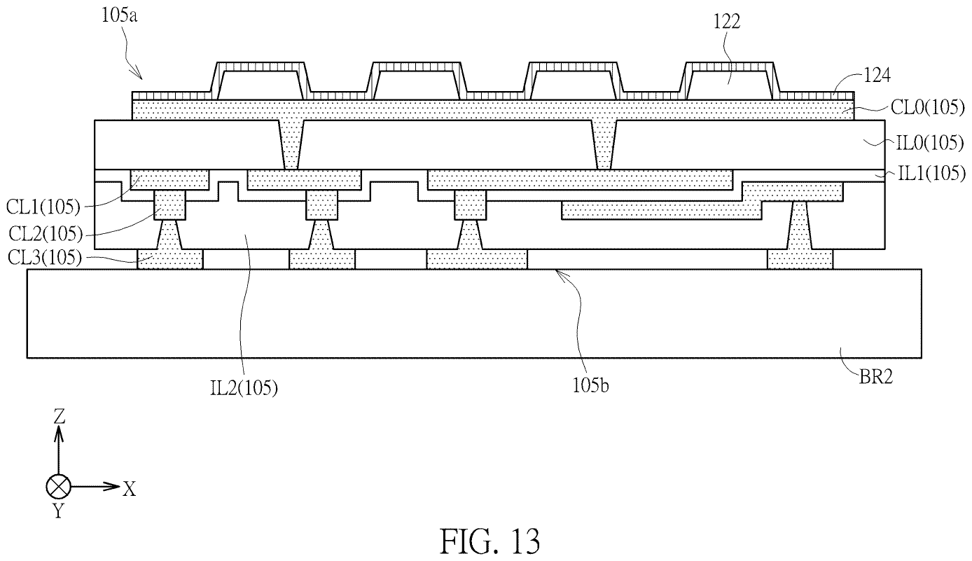

As shown in FIG. 13, the film structure 105 is transferred from the first carrier board BR1 to a second carrier board BR2 by a suitable transferring process, such that the second carrier board BR2 is on the second side 105b of the film structure 105 (the first side 105a and the second side 105b are two opposite sides of the film structure 105 in the direction Z). In the transferring process of an embodiment, the second carrier board BR2 is disposed on the second side 105b of the film structure 105, and then, the first carrier board BR1 is removed from the first side 105a of the film structure 105 by a suitable release process.

After that, a patterning process is performed on the insulating layer IL0. Then, the conductive layer CL0 is formed on the insulating layer IL0, and a patterning process is optionally performed on the conductive layer CL0. Note that the conductive layer CL0 may belong to the film structure 105. Accordingly, the film structure 105 of this embodiment includes the conductive layers CLy and the insulating layers ILx and the inorganic material dielectric layer ILn, and these layers of the film structure 105 are configured to form the component(s) 110.

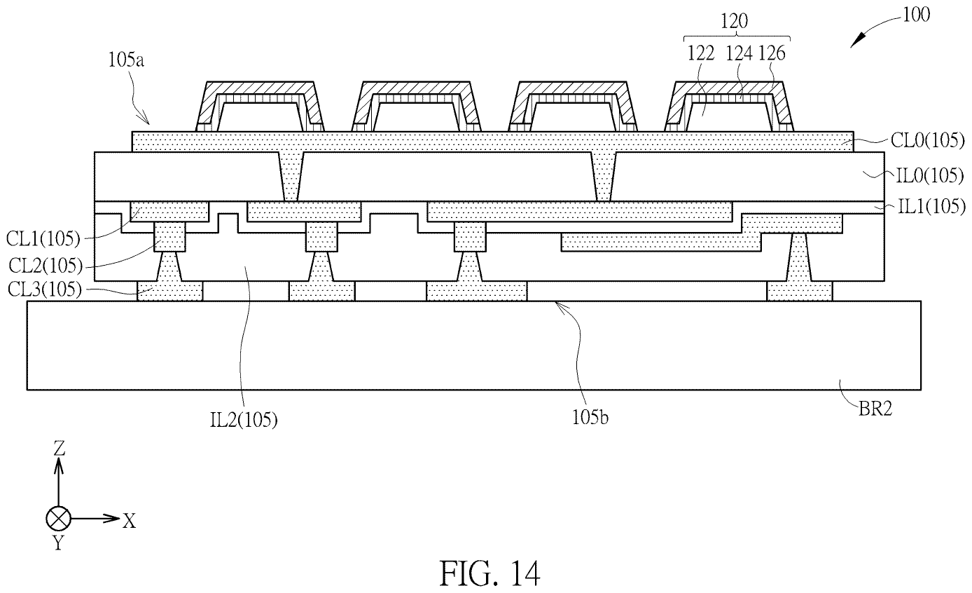

As shown in FIG. 13 to FIG. 14, at least one probe 120 is formed on the first side 105a of the film structure 105, such that the flexible detecting film 100 including the film structure 105 and the probe 120 is formed. For example, a patterned photoresist layer may be formed on the conductive layer CL0. Then, the patterned insulating material 122 is formed on the conductive layer CL0. For instance, the insulating material 122 may be formed in the region(s) which is not covered by the photoresist layer, so as to form the patterned structure(s). In some of the embodiment, a size of a side of the insulating material 122 close to the conductive layer CL0 may be greater than a size of another side of the insulating material 122 away from the conductive layer CL0. For instance, the insulating material 122 may include the elastic material. After the photoresist layer is removed, a first conductive material 124 is formed on the patterned insulating material 122.

In FIG. 14, a patterned second conductive material 126 is formed on the first conductive material 124, wherein the second conductive material 126 overlaps the patterned insulating material 122 in the direction Z. For instance, another photoresist layer may be formed on the first conductive material 124, and then, the second conductive material 126 may be formed on the first conductive material 124. Because of the existence of this photoresist layer, the second conductive material 126 may be formed in the region(s) which is not covered by this photoresist layer, such that the patterned second conductive material 126 may be formed.

Then, a patterning process is performed on the first conductive material 124, so as to form a patterned first conductive material 124. For instance, in this patterning process, the second conductive material 126 may serve as an etching stop layer, such that the first conductive material 124 may be patterned based on the second conductive material 126. Accordingly, the patterned first conductive material 124 and the patterned second conductive material 126 are formed on the patterned insulating material 122, so as to complete the manufacture of the probe 120, thereby completing the manufacture of the flexible detecting film 100.

Then, as shown in FIG. 1, the second carrier board BR2 is removed, and the flexible detecting film 100 is disposed on the supporting layer SP, such that the film structure 105 is disposed between the probe 120 and the supporting layer SP, so as to complete the manufacture of the test device TD. Furthermore, the first circuit board CB1 may be connected to the flexible detecting film 100, and the second circuit board CB2 may be connected to the supporting layer SP, so as to complete the structure shown in FIG. 1.

In summary, since the component(s) of the flexible detecting film of the present disclosure is integrated in the film structure, and the first component and the probe of the flexible detecting film are overlapped with each other, the distance between the first component of the flexible detecting film and the unit under test is reduced, such that the length of the signal trace is reduced, so as to reduce the parasitic effect caused by the test device. Accordingly, the test accuracy and the test stability of the test device are enhanced, and the test error of the test device is reduced.

Although the embodiments and their advantages of the present disclosure have been described as above, it should be understood that any person having ordinary skill in the art can make changes, substitutions, and modifications without departing from the spirit and scope of the present disclosure. In addition, the protecting scope of the present disclosure is not limited to the processes, machines, manufactures, material compositions, devices, methods and steps in the specific embodiments described in the description. Any person having ordinary skill in the art can understand the current or future developed processes, machines, manufactures, material compositions, devices, methods and steps from the content of the present disclosure, and then, they can be used according to the present disclosure as long as the same functions can be implemented or the same results can be achieved in the embodiments described herein. Thus, the protecting scope of the present disclosure includes the above processes, machines, manufactures, material compositions, devices, methods and steps. Moreover, each claim constitutes an individual embodiment, and the protecting scope of the present disclosure also includes the combination of each claim and each embodiment. The protecting scope of the present disclosure shall be determined by the appended claims.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A test device, comprising:
a flexible detecting film; and
a supporting layer supporting the flexible detecting film;
wherein the flexible detecting film comprises at least one probe and at least one first component, the at least one first component overlaps the at least one probe, the at least one first component is disposed between the at least one probe and the supporting layer, the flexible detecting film comprises an organic material, and an elongation ratio of the organic material is greater than an elongation ratio of the supporting layer.

2. The test device of claim 1, wherein the at least one first component comprises a capacitor, and the capacitor comprises an inorganic material dielectric layer.

3. The test device of claim 2, wherein a thickness of the inorganic material dielectric layer is greater than or equal to 1000 Å and less than or equal to 5000 Å.

4. The test device of claim 2, wherein the inorganic material dielectric layer comprises silicon oxide, silicon nitride or silicon oxynitride.

5. The test device of claim 2, wherein the flexible detecting film comprises an insulating layer, the insulating layer comprises the organic material, and a dielectric constant of the inorganic material dielectric layer is greater than a dielectric constant of the insulating layer.

6. The test device of claim 2, wherein the flexible detecting film comprises an insulating layer, the insulating layer has an insulating opening, the inorganic material dielectric layer is disposed in the insulating opening, and a dielectric constant of the inorganic material dielectric layer is greater than a dielectric constant of the insulating layer.

7. The test device of claim 1, further comprising a protective layer surrounding the flexible detecting film.

8. The test device of claim 1, wherein the supporting layer overlaps the at least one probe and at least a portion of the at least one first component in a normal direction of the supporting layer.

9. The test device of claim 1, further comprising a first circuit board electrically connected to the at least one first component, wherein the first circuit board has a circuit board opening, and the supporting layer passes through the circuit board opening.

10. The test device of claim 9, wherein the flexible detecting film has a first region and a second region, the supporting layer overlaps the first region and does not overlap the second region in a normal direction of the supporting layer, the first circuit board overlaps the second region and does not overlap the first region in the normal direction, and the at least one probe and the at least one first component are disposed in the first region.

11. The test device of claim 10, wherein the flexible detecting film comprises at least one second component disposed in the second region and electrically connected to the first circuit board.

12. The test device of claim 10, wherein the flexible detecting film has a third region between the first region and the second region, the third region is disposed in the circuit board opening and between the first circuit board and the supporting layer, and the flexible detecting film comprises at least one third component disposed in the third region.

13. The test device of claim 1, further comprising a second circuit board, wherein the supporting layer is disposed between the flexible detecting film and the second circuit board in a normal direction of the supporting layer.

14. The test device of claim 1, wherein the at least one first component comprises a capacitor and an inductor.

15. The test device of claim 1, wherein the at least one probe comprises an elastic material, and an elongation ratio of the elastic material ranges from 20% to 900%.

16. The test device of claim 1, wherein the test device tests a unit under test by directly contacting the unit under test with the at least one probe.

17. A manufacturing method of a test device, comprising following steps:
providing a first carrier board;
forming at least one insulating layer and at least one conductive layer on the first carrier board to form a film structure, wherein the first carrier board is on a first side of the film structure, the film structure comprises at least one first component, and one of the at least one insulating layer comprises an organic material;
transferring the film structure from the first carrier board to a second carrier board, wherein the second carrier board is on a second side of the film structure, and the second side and the first side are two opposite sides of the film structure;
forming at least one probe on the first side of the film structure to form a flexible detecting film comprising the film structure and the at least one probe, wherein the at least one probe overlaps at least a portion of the at least one first component; and
disposing the flexible detecting film on a supporting layer, wherein the at least one first component is disposed between the at least one probe and the supporting layer.

18. The manufacturing method of claim 17, wherein the at least one first component comprises a capacitor, the capacitor comprises an inorganic material dielectric layer comprised in the at least one insulating layer, and a dielectric constant of the inorganic material dielectric layer is greater than a dielectric constant of the organic material.

19. The manufacturing method of claim 17, wherein the at least one insulating layer comprises an inorganic material dielectric layer and a first insulating layer, the first insulating layer has an insulating opening, the inorganic material dielectric layer is disposed in the insulating opening, and a dielectric constant of the inorganic material dielectric layer is greater than a dielectric constant of the first insulating layer.

20. The manufacturing method of claim 17, wherein the step of forming the at least one probe comprises:
forming a patterned insulating material on the first side of the film structure; and
forming a patterned conductive material on the patterned insulating material.
